(19) United States
(12) Patent Application Publication
(10) Pub. No.: US 2002/0145854 A1
(43) Pub. Date: Oct. 10, 2002

(54) Composite heat-dissipating structure

(76) Inventor: Chieh-Wei Lin, Taoyuan Shien (TW)

Correspondence Address: Gazdzinski & Associates, 3914 Murphy Canyon Road, Suite A232, San Diego, CA, 92123, US

(21) Appl. No.: 10/045,113

(22) Filed: Oct. 18, 2001

(30) Foreign Application Priority Data
Apr. 6, 2001 (TW) 090205377

(51) Int. Cl. H05K 7/20

(52) U.S. Cl. 361/719; 174/16.3; 165/185

(57) ABSTRACT

A composite heat-dissipating structure applied in a circuit board is disclosed. The composite heat-dissipating structure includes a first heat-dissipating element connected to a heat-generating device, and a second heat-dissipating element detachably connected to the first heat-dissipating element, wherein the selection of the first and second heat-dissipating elements is dependent on a heat-generating rate of the heat-generating device and a particular space limitation for achieving a heat-dissipating effect.

### FIELD OF THE INVENTION

The present invention relates to a heat-dissipating structure, and more particularly to a composite heat-dissipating structure.

### BACKGROUND OF THE INVENTION

Along with the progression of technology, currently, the processing speed of the systemic host is fast and fast. However, along the working frequency largely increases, the working current also increases and further the heat generated by a heat-generating device on the circuit broad increases. The heat will cause a negative effect on the systemic stability of the integrated circuit. Furthermore, it is an important issue to decrease the temperature generated from the heat-generating device by the heat-dissipating element, especially in a server because it requires long-term operation.

FIGS. 1A-1C are diagrams illustrating a heat-dissipating structure according to the prior art. As shown in FIG. 1A, a thermal conductive plate 11 and a heat-generating device 10 are fixed on a circuit broad (not shown). The thermal conductive plate 11 is used for increasing the heat-dissipating effect. However, the practice value of the requirement in heat-dissipating amount is generally over than the estimated value of that. Thus, once the estimated value does not conform to the practice value of the requirement, it is necessary to make a new die of the heat-dissipating element, such as a thermal conductive plate having a plurality of cooling fins 111 as shown in FIG. 1B, for fitting the requirement of heat-dissipating amount. However, if the requirement of the heat-dissipating amount increases again, another new die of the heat-dissipating element, such as a heat sink 112 as shown in FIG. 1C, is required to make to fit the space limitation on the circuit broad.

Accordingly, the prior art has the following disadvantages:

1. Because the thermal conductive plate or the heat sink for each designed circuit has to be specifically designed and made, so it is time-consumption and material-consumption.

2. The current product is required to conform the safety standard, so a gap 12 as shown in FIG. 1C is necessary for fitting the safety standard. Therefore, it will increase the difficulty of the processing.

3. When the heat-generating device in FIG. 1C is broken, it cannot be changed due to the heat sink is not removable. Thus, it causes the difficulty of maintaining the heat-generating device.

Therefore, the purpose of the present invention is to develop a composite heat-dissipating structure to deal with the above situations encountered in the prior art.

### SUMMARY OF THE INVENTION

It is therefore an object of the present invention to provide a composite heat-dissipating structure in flexibly responding to a practice requirement for increasing the assembling possibility of the product, increasing space utilization, and reducing the cost.

It is another object of the present invention to provide a composite heat-dissipating structure for easily and quickly maintaining devices on the circuit broad.

It is an additional object of the present invention to provide a composite heat-dissipating structure for easily changing the relative position of the heat-dissipating elements.

According to an aspect of the present invention, there is provided a composite heat-dissipating structure including a first heat-dissipating element connected to a heat-generating device, and a second heat-dissipating element detachably connected to the first heat-dissipating element, wherein the selection of the first and second heat-dissipating elements is dependence on a heat-generating rate of the heat-generating device and a particular space limitation for achieving a heat-dissipating effect.

Preferably, the first and second heat-dissipating elements are specified thermal conductive plates. The first heat-dissipating element preferably is a first type of a thermal conductive plate having a first specification while the second heat-dissipating element is preferably a second type of a thermal conductive plate having a second specification.

Preferably, the specified thermal conductive plates have a specification of thermal conductive wattage.

Preferably, the composite heat-dissipating structure further includes a third heat-dissipating element detachably connected to the first or second heat-dissipating elements. For example, the third heat-dissipating element is a heat sink or a thermal conductive plate having a specification of thermal conductive wattage. For example, the heat-dissipating elements are connected to each other by screwing.

For example, the connections between the first heat-dissipating element and the heat-generating device and between the first and second heat-dissipating elements are executed by screwing. Preferably, the first and second heat-dissipating elements are made of metal.

For example, the composite heat-dissipating structure is fixed on a circuit broad by screwing.

Preferably, the contact surfaces between the first and second heat-dissipating elements and between heat-generating device and the first heat-dissipating element are applied to a thermal conductive medium for conducting heat from the heat-generating device to the first and second heat-dissipating elements. For example, the thermal conductive medium is a cooling ointment.

According to another aspect of the present invention, there is provided a composite heat-dissipating structure disposed on a circuit broad. The composite heat-dissipating structure includes a first heat-dissipating element detachably connected to a heat-generating device, a second heat-dissipating element detachably connected to the first heat-dissipating element, and a third heat-dissipating element detachably connected to the second-dissipating element, wherein the selections of the first, second and third heat-dissipating elements are dependence on a heat-generating rate of the heat-generating device and a particular space limitation for achieving a heat-dissipating effect.

Preferably, each of first, second and third heat-dissipating elements is a specified thermal conductive plate or a specified heat sink.

Preferably, the connections between the first heat-dissipating element and the heat-generating device, between the first and second heat-dissipating elements, and between the second and third heat-dissipating elements are executed by screwing.

The present invention may best be understood through the following description with reference to the accompanying drawings, in which:

### BRIEF DESCRIPTION OF THE DRAWINGS

FIGS. 1A-1C are diagrams illustrating a heat-dissipating structure according to the prior art; and

FIG. 2 is a diagram illustrating a composite heat-dissipating structure according to a preferred embodiment of the present invention.

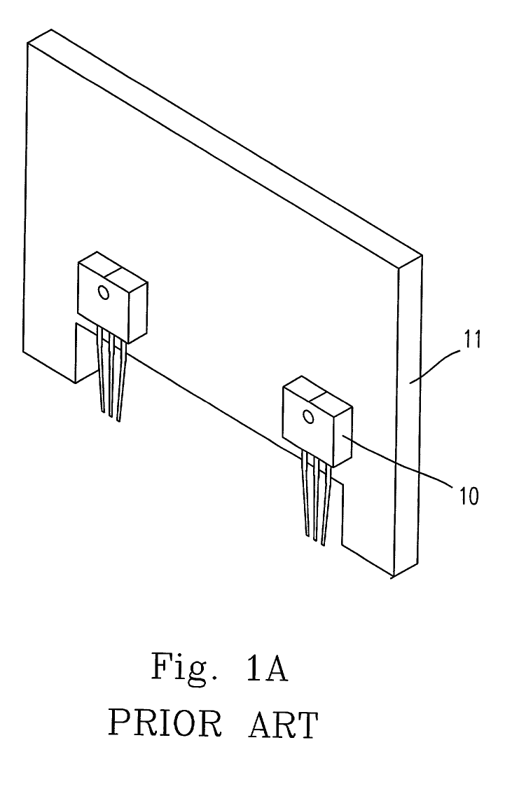

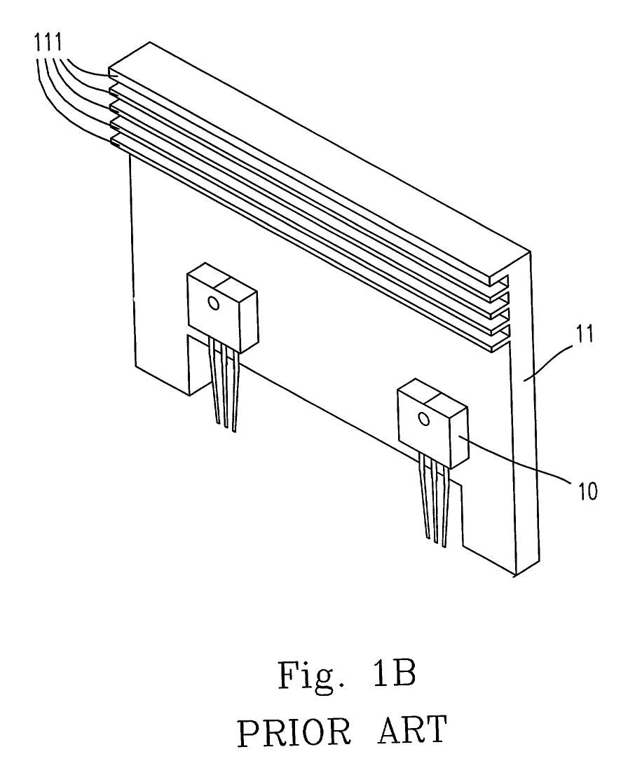

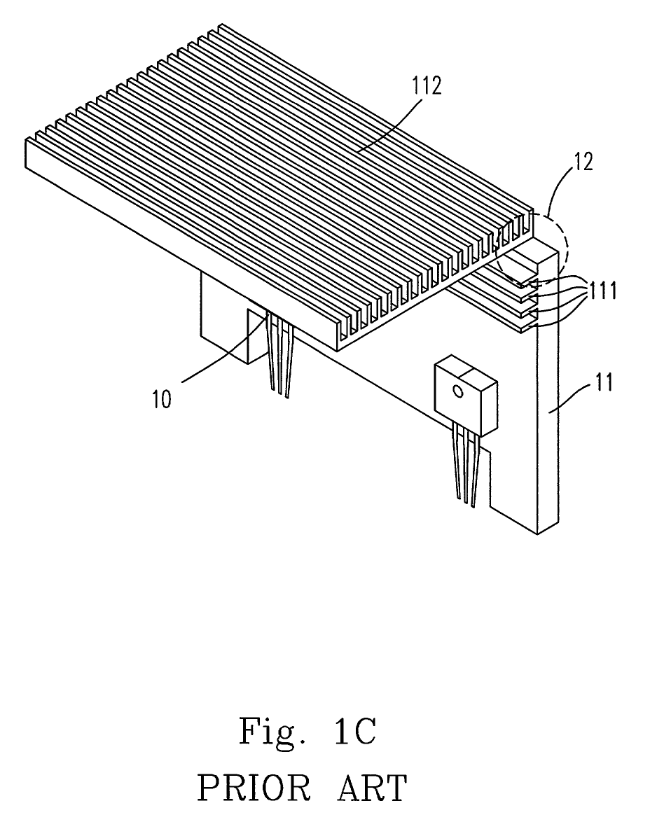

### DETAILED DESCRIPTION OF THE PREFERRED EMBODIMENTS

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

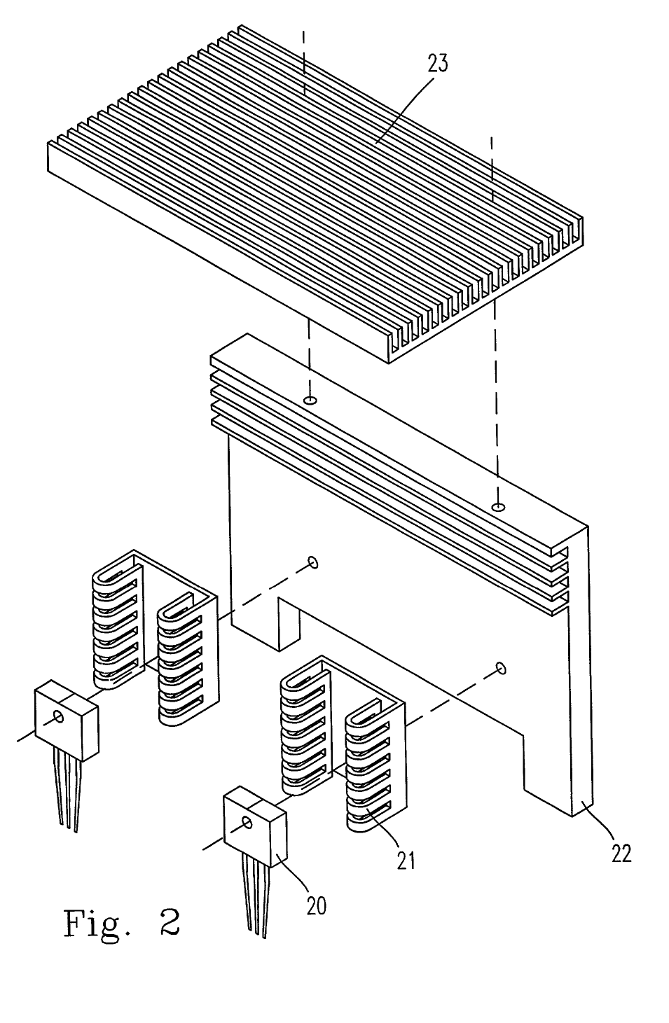

As shown in FIG. 2, the present invention provides a composite heat-dissipating structure applied in a circuit broad (not shown). The composite heat-dissipating structure includes a first thermal conductive plate 21 connected to a heat-generating device 20, a second thermal conductive plate 22 connected to the thermal conductive plate 21, and a heat sink 23 connected to the second thermal conductive plate 22. The first and second thermal conductive plates 21, 22 are different types of thermal conductive plates in different shapes, different sizes and different specifications. The selection of thermal conductive plates or heat sink is dependent on the heat-generating rate of the heat-generating device and the space limitation on the circuit broad. The thermal conductive plates in different specifications are distinguished by different thermal conductive wattages. Hence, the composite heat-dissipating structure can be designed according to the particular requirement in order to achieve the cooling effect. Thus, the circuit broad can normally operate under a proper temperature.

Moreover, the first thermal conductive plates 21 are connected to the heat-generating devices 20 and the second thermal conductive plate 22 by screwing. The second thermal conductive plate 22 is also connected to the heat sink 23 by screwing. Furthermore, a thermal conductive medium such as a cooling ointment is applied into the contact surfaces and points between the heat-generating device 20 and the first thermal conductive plate 21, between those thermal conductive plates 21, 22, and between the second conductive plate 22 and the heat sink 23 for enhancing the heat conduction from the heat-generating device 20 to each thermal conductive plate 21, 22 and the heat sink 23.

In addition, the first and second thermal conductive plates and the heat sink are made of metal.

In sum, the composite heat-dissipating structure according to the present invention can efficiently solve the problems of the prior art and has the following advantages:

1. The composite heat-dissipating structure according to the present invention is flexibly composed and changed in response to the particular requirement. Thus, it can increase the assembling possibility of the product, increase space utilization, and reduce the cost.

2. For conforming to the safety requests, it is only to change the connected point between the thermal conductive plates to leave a gap.

3. When the heat-generating device located below the heat sink is broken, the heat sink is easily removed. Thus, the broken heat-generating device can be changed easily and quickly.

While the invention has been described in terms of what are presently considered to be the most practical and preferred embodiments, it is to be understood that the invention need not to be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A composite heat-dissipating structure comprising:
a first heat-dissipating element connected to a heat-generating device; and
a second heat-dissipating element detachably connected to said first heat-dissipating element, wherein the selection of said first and second heat-dissipating elements is dependent on a heat-generating rate of said heat-generating device and a particular space limitation for achieving a heat-dissipating effect.

2. The composite heat-dissipating structure according to claim 1 wherein said first and second heat-dissipating elements are specified thermal conductive plates.

3. The composite heat-dissipating structure according to claim 2 wherein said first heat-dissipating element is a first type of a thermal conductive plate having a first specification.

4. The composite heat-dissipating structure according to claim 2 wherein said second heat-dissipating element is a second type of a thermal conductive plate having a second specification.

5. The composite heat-dissipating structure according to claim 2 wherein said specified thermal conductive plates have a specification of thermal conductive wattage.

6. The composite heat-dissipating structure according to claim 1 further comprising a third heat-dissipating element detachably connected to one of said first and second heat-dissipating elements.

7. The composite heat-dissipating structure according to claim 6 wherein said third heat-dissipating element is one of a heat sink and a thermal conductive plate having a specification of thermal conductive wattage.

8. The composite heat-dissipating structure according to claim 6 wherein said heat-dissipating elements are connected by screwing.

9. The composite heat-dissipating structure according to claim 1 wherein the connections between said first heat-dissipating element and said heat-generating device and between said first and second heat-dissipating elements are executed by screwing.

10. The composite heat-dissipating structure according to claim 1 wherein said first and second heat-dissipating elements are made of metal.

11. The composite heat-dissipating structure according to claim 1 wherein said composite heat-dissipating structure is fixed on a circuit broad by screwing.

12. The composite heat-dissipating structure according to claim 1 wherein the contact surfaces between said first and second heat-dissipating elements and between heat-generating device and said first heat-dissipating element are applied to a thermal conductive medium for conducting heat from said heat-generating device to said first and second heat-dissipating elements.

13. The composite heat-dissipating structure according to claim 1 wherein said thermal conductive medium is a cooling ointment.

14. A composite heat-dissipating structure disposed on a circuit broad, comprising:
a first heat-dissipating element detachably connected to a heat-generating device; and
a second heat-dissipating element detachably connected to said first heat-dissipating element;
a third heat-dissipating element detachably connected to said second-dissipating element, wherein the selections of said first, second and third heat-dissipating elements are dependent on a heat-generating rate of said heat-generating device and a particular space limitation for achieving a heat-dissipating effect.

15. The composite heat-dissipating structure according to claim 14 wherein each of said first, second and third heat-dissipating elements is one of specified thermal conductive plate and specified heat sink.

16. The composite heat-dissipating structure according to claim 14 wherein the connections between said first heat-dissipating element and said heat-generating device, between said first and second heat-dissipating elements, and between said second and third heat-dissipating elements are executed by screwing.
